(19) United States
(12) Patent Application Publication
(10) Pub. No.: US 2003/0028835 A1
(43) Pub. Date: Feb. 6, 2003

(54) Semiconductor integrated circuit

(75) Inventor: Katsuya Ishikawa, Kawasaki (JP)

Correspondence Address: ARENT FOX KINTNER PLOTKIN & KAHN, PLLC, Suite 600, 1050 Connecticut Avenue, Washington, DC, 20036-5339, US

(73) Assignee: Fujitsu Limited

(21) Appl. No.: 10/102,709

(22) Filed: Mar. 22, 2002

(30) Foreign Application Priority Data
Aug. 2, 2001 (JP) 2001-234798

(51) Int. Cl. G11C 29/00

(52) U.S. Cl. 714/718

(57) ABSTRACT

A semiconductor integrated circuit that can accurately measure margins for input-output characteristics in the case of transferring data at a high speed between semiconductor chips mounted in the same package. A semiconductor chip includes a first delay section selected to perform a hold margin test in the case of transferring data to a separate semiconductor chip for delaying a clock signal and a second delay section selected to perform a setup margin test in the case of transferring data to the separate semiconductor chip for delaying output data. Furthermore, the semiconductor chip includes a third delay section selected to perform a hold margin test on a second latch section in the case of data being input from the separate semiconductor chip for delaying a clock signal from a clock input section and a fourth delay section selected to perform a setup margin test on the second latch section in the case of data being input from the separate semiconductor chip for delaying input data.

### BACKGROUND OF THE INVENTION

(1) Field of the Invention

This invention relates to a semiconductor integrated circuit in which a plurality of semiconductor chips are mounted in the same package and, more particularly, to a semiconductor integrated circuit including a structure for performing input-output characteristic tests between semiconductor chips in the same package.

(2) Description of the Related Art

In recent years semiconductor integrated circuits in which semiconductor chips (a memory, such as a DRAM, and a logic circuit, for example), which have conventionally been manufactured by different processes, are mounted in the same package as a multichip module (MCM) or multichip package (MCP) are increasing in number. A board the wiring capacitance of which is high is not used in such a semiconductor integrated circuit, so hope of high-speed data transfer between semiconductor chips is running high.

By the way, each of semiconductor chips to be mounted in MCMs or MCPs is tested first in a wafer state. Semiconductor chips which meet prescribed conditions are used to produce integrated circuits. If a high-frequency clock signal is used, there is a limit to performing input-output characteristic tests, such as measuring AC characteristics at an input-output terminal, in a wafer state. Conventionally, tests have been performed by relaxed standards or tests have not been made. In the latter cases, standards which can ensure that percent defective will be small are set and integrated circuits are used with the frequency of data transfer between semiconductor chips kept low.

Now, a setup/hold margin test performed on semiconductor chips in conventional MCMs and MCPs will be described. FIG. 14 shows the structure of data input-output blocks on semiconductor chips in a conventional MCM or MCP.

In FIG. 14, a logic chip 110 and a synchronous dynamic random access memory (SDRAM) 120 are used as semiconductor chips mounted in a semiconductor integrated circuit as an MCM or MCP and the schematic structure of data input-output blocks between the logic chip 110 and SDRAM 120 is shown. The logic chip 110 includes a flip-flop (FF) 111 for latching data to be transferred to the SDRAM 120 with the rise timing of a clock signal, a delay circuit 112 for delaying a signal output from the FF 111, an FF 113 for latching data transferred from the SDRAM 120 by an input clock signal, an FF 114 for latching data output from the FF 113 by a clock signal, and an input-output section 115 for outputting data and a clock signal to the SDRAM 120 and accepting data and a clock signal. The SDRAM 120 includes an input-output section 121 for accepting data and a clock signal and outputting data.

The FF 111 accepts input control data, such as commands, addresses, and data to be written into the SDRAM 120, and latches this control data with the rise timing of a clock signal from the inside of the logic chip 110. The delay circuit 112 delays data output from the FF 111 so that hold time at the next rise of a clock signal will be satisfied at the time of the SDRAM 120 receiving control data transferred from the logic chip 110. The input-output section 115 outputs data output from the FF 111 to the SDRAM 120, outputs a clock signal to the SDRAM 120, and inputs the clock signal again to the logic chip 110.

The input-output section 121 on the SDRAM 120 accepts various pieces of control data and a clock signal. Control data is imported in synchronization with this clock signal and data is written. In this case, data will be written into a specified address in compliance with a write instruction from the logic chip 110.

When an instruction to read data is transferred from the logic chip 110, data is read from a specified address in the SDRAM 120. This data is latched by a clock signal input from the input-output section 121 and then is sent to the logic chip 110.

The input-output section 115 on the logic chip 110 accepts data input from the SDRAM 120 and a clock signal once output from the logic chip 110 and supplies the data and clock signal to the FF 113. The FF 113 latches the supplied data by this clock signal and supplies the data to the FF 114. This cancels delays for a clock signal which will occur in the circuits of or at the terminals of the input-output sections 115 and 121. The FF 114 latches supplied data by a clock signal from the inside of the logic chip 110 and outputs the data.

In FIG. 14, to simplify the descriptions, it is assumed that data is transferred over data buses only in one direction.

Now, operation in a setup/hold margin test performed between the logic chip 110 and SDRAM 120 will be described. FIG. 15 is a time chart showing a signal in each section at the time of data being written into the SDRAM 120.

If data is written from the logic chip 110 to the SDRAM 120, on the logic chip 110 side control data for writing to the SDRAM 120 is latched by an internal clock and then is delayed by the delay circuit 112 so that hold time will be satisfied at the time of the SDRAM 120 receiving. Therefore, the rise timing of output data DOUT1 as shown in FIG. 15(B) delays to a clock signal CLKO output from the input-output section 115 as shown in FIG. 15(A).

On the other hand, on the SDRAM 120 side input data DIN1 as shown in FIG. 15(D) is imported with the rise timing of clock signal CLKI1 input from the logic chip 110 to the input-output section 121 as shown in FIG. 15(C). Standards for setup time Ts1 and hold time Th1 needed at the time of data being imported to the SDRAM 120 are set with an error caused by the use of a tester at a test time taken into consideration. Therefore, a setup standard Tso1 in which a tester error Te1 is taken into consideration and a hold standard Tho1 in which a tester error Te2 is taken into consideration are set as actual standards used in the tests.

Moreover, on the logic chip 110 side standards for output characteristics must be set with tester errors Te3 and Te4 taken into consideration. Therefore, minimum delay time MIN-DLY1 in the delay circuit 112 needed to meet the hold standard Tho1 on the SDRAM 120 side will be given by adding the tester error Te4 on the logic chip 110 side to the hold standard Tho1 for the SDRAM 120 including the hold time Th1 and tester error Te2.

Furthermore, maximum delay time MAX-DLY1 needed to meet the setup standard Tso1 on the SDRAM 120 side is determined from the minimum delay time MIN-DLY1 with variation in the quality of manufactured logic chips 110 taken into consideration. A maximum transfer frequency at the time of data being written to the SDRAM 120 is determined by time obtained by adding the tester error Te3 on the logic chip 110 side and the setup standard Tso1 on the SDRAM 120 side to the maximum delay time MAX-DLY1.

FIG. 16 is a time chart showing a signal in each section at the time of data being read from the SDRAM 120.

If data is read from the SDRAM 120 to the logic chip 110, on the logic chip 110 side the FF 113 latches data DIN2 input from the SDRAM 120 as shown in FIG. 16(D) by a clock signal CLKI2 input again as shown in FIG. 16(C). A setup standard Tso2 obtained by adding tester error Te5 to setup time Ts2 needed in this case and a hold standard Tho2 obtained by adding tester error Te6 to hold time Th2 needed in this case are set as actual standards used in the tests.

On the other hand, on the SDRAM 120 side the rise timing of output data DOUT2 as shown in FIG. 16(B) is delayed to the clock signal CLKI1 input from the logic chip 110 as shown in FIG. 16(A). In this case, maximum delay time MAX-DLY2 and minimum delay time MIN-DLY2 are determined with tester errors Te7 and Te8 on the SDRAM 120 side taken into consideration so that the setup standard Tso2 and hold standard Tho2 at the time of receiving on the logic chip 110 side will be met.

A maximum transfer frequency at the time of data being read from the SDRAM 120 therefore is determined by time obtained by adding up the maximum delay time MAX-DLY2 and tester error Te7 on the SDRAM 120 side and the tester error Te5 and setup standard Tso2 on the logic chip 110 side.

In the data write operation shown in FIG. 15, the maximum transfer frequency calculated by adding the setup standard Tso1 on the SDRAM 120 side to the maximum delay time MAX-DLY1 and tester error Te3 on the logic chip 110 side matches the frequency of the clock signal. Therefore, if the frequency of the clock signal is increased in a test performed by the use of a tester, it is difficult to guarantee a normal data transfer which meets both the setup standard Tso1 and hold standard Tho1 on the SDRAM 120 side. Similarly, in the data read operation shown in FIG. 16, the maximum transfer frequency matches the frequency of the clock signal. Therefore, if the frequency of the clock signal is increased, it is difficult to guarantee a normal data transfer.

As stated above, a data transfer rate which can be guaranteed will be limited by the influence of tester errors which will occur during a setup/hold margin test performed on input-output blocks on semiconductor chips connected to closed signal lines in MCMs and MCPs. A margin for setup/hold time therefore cannot be measured accurately at the time of data being transferred at a high frequency. As a result, defective products insufficient in a margin for setup/hold time cannot be rejected reliably.

Moreover, with the structure including the logic chip 110 and SDRAM 120 as shown in, for example, FIG. 14, the influence of variation in the process, temperature, and voltage etc. is reduced by compensating delay time in the delay circuit 112 located on a signal line via which the logic chip 110 outputs data in order to increase the processing speed of the interface between the semiconductor chips. With an MCM or MCP in which these semiconductor chips are mounted, however, if the phase of a clock signal used for latching is advanced to ensure a hold margin for the FF 113 on data input to the logic chip 110, margins for, for example, precision in the compensation of delay time in the delay circuit 112 cannot be measured.

### SUMMARY OF THE INVENTION

In order to address such problems, the present invention was made. In other words, an object of the present invention is to provide a semiconductor integrated circuit which can accurately measure margins for input-output characteristics in the case of transferring data at a high speed between semiconductor chips mounted in the same package.

In order to achieve the above object, a semiconductor integrated circuit in which a plurality of semiconductor chips are mounted in the same package is provided. One of the plurality of semiconductor chips includes first latch section for latching output data to be output to a separate semiconductor chip of the plurality of semiconductor chips mounted in the same package by a clock signal, clock output section for outputting the clock signal to the separate semiconductor chip, data output section for outputting the output data output from the first latch section to the separate semiconductor chip, first delay section selectively located before the clock output section for delaying the clock signal, and second delay section selectively located between the first latch section and the data output section for delaying the output data, where the first delay section is selected to perform a hold margin test at the time of the output data being input to the separate semiconductor chip and the second delay section is selected to perform a setup margin test at the time of the output data being input to the separate semiconductor chip.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 is a view for describing the principles underlying a semiconductor integrated circuit according to the present invention.

FIG. 2 is a view showing the structure of a first embodiment of the present invention.

FIG. 3 is a time chart for describing operation at the time of a setup margin test being performed on an SDRAM in the first embodiment.

FIG. 4 is a time chart for describing operation at the time of a hold margin test being performed on the SDRAM in the first embodiment.

FIG. 5 is a time chart for describing operation at the time of a setup margin test being performed on a logic chip in the first embodiment.

FIG. 6 is a time chart for describing operation at the time of a hold margin test being performed on the logic chip in the first embodiment.

FIG. 7 is a view showing the structure of a second embodiment of the present invention.

FIG. 8 is a time chart for describing operation at the time of a setup/hold margin test being performed on an SDRAM in the second embodiment.

FIG. 9 is a time chart for describing operation at the time of a setup/hold margin test being performed on a logic chip in the second embodiment.

FIG. 10 is a view showing the structure of a third embodiment of the present invention.

FIG. 11 is a view showing the structure of a fourth embodiment of the present invention.

FIG. 12 is a time chart for describing operation in a setup margin test performed in the case of data being read from an SDRAM.

FIG. 13 is a time chart for describing operation in a hold margin test performed in the case of data being read from an SDRAM.

FIG. 14 is a view showing the structure of data input-output blocks on semiconductor chips in a conventional MCM or MCP.

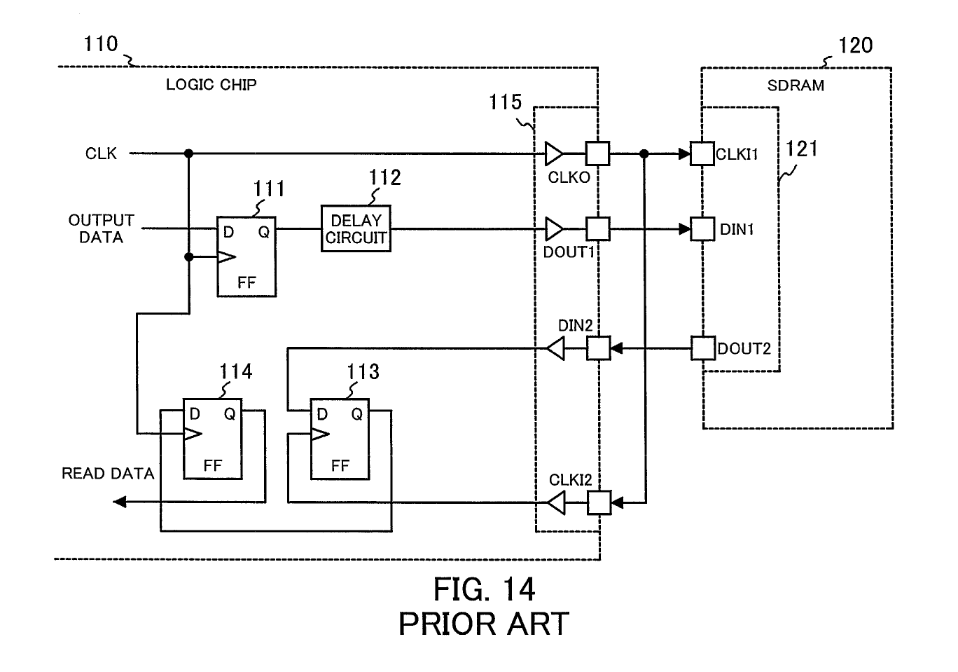

FIG. 15 is a time chart showing the relationship between a signal in each section and time at the time of data being written into an SDRAM.

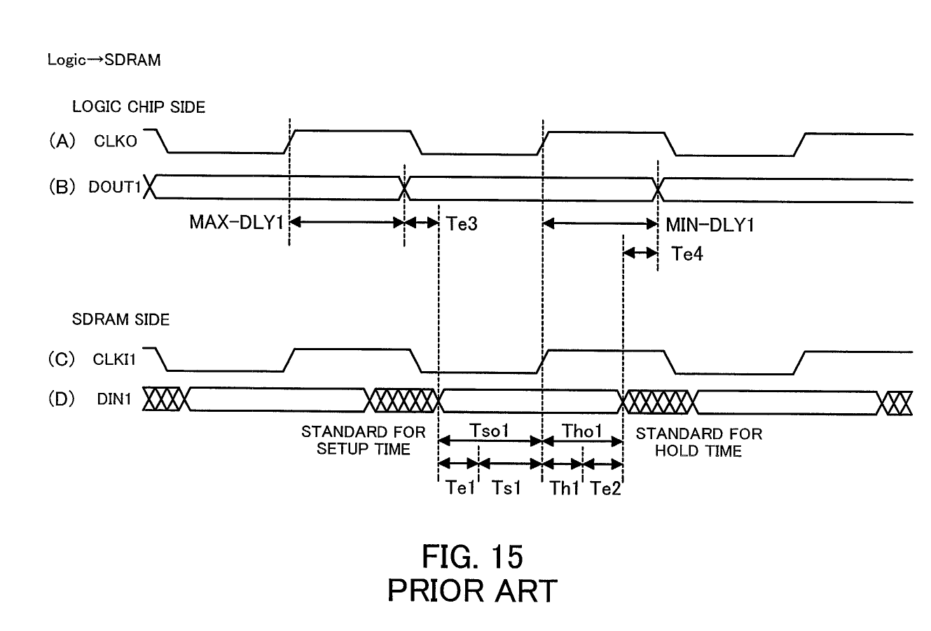

FIG. 16 is a time chart showing the relationship between a signal in each portion and time at the time of data being read from an SDRAM.

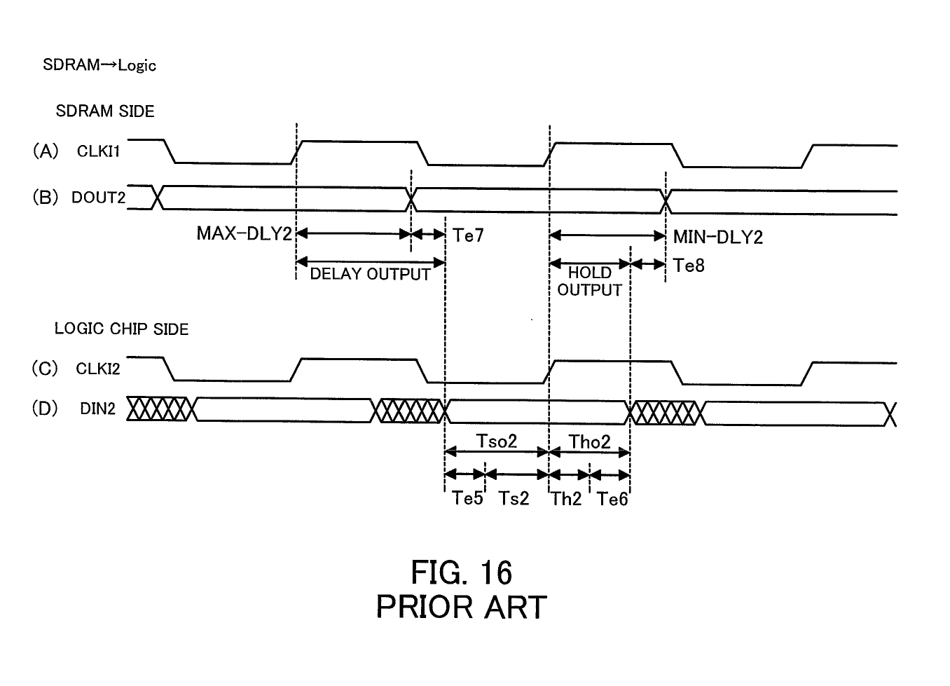

### DESCRIPTION OF THE PREFERRED EMBODIMENTS

Embodiments of the present invention will now be described with reference to the drawings.

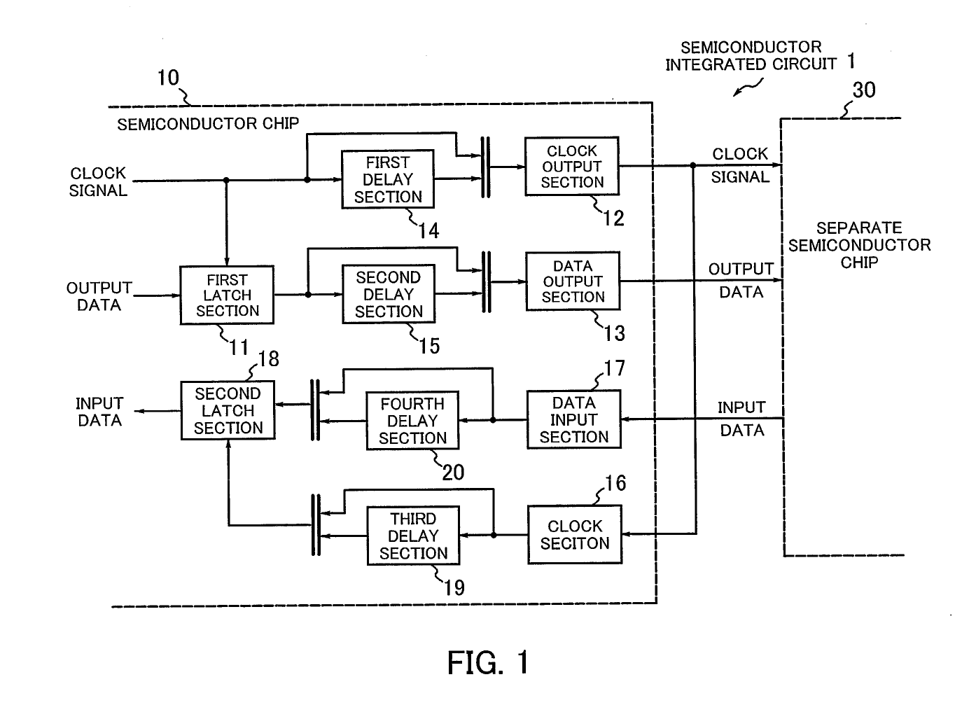

FIG. 1 is a view for describing the principles underlying a semiconductor integrated circuit according to the present invention.

In a semiconductor integrated circuit 1 according to the present invention as shown in FIG. 1, a plurality of semiconductor chips are mounted in the same package. A semiconductor chip 10 in the semiconductor integrated circuit 1 as shown in FIG. 1 includes first latch section 11 for latching output data to be output to a separate semiconductor chip 30 mounted in the same package by a clock signal, clock output section 12 for outputting a clock signal to the separate semiconductor chip 30, data output section 13 for outputting output data output from the first latch section 11 to the separate semiconductor chip 30, first delay section 14 selectively located before the clock output section 12 for delaying a clock signal, and second delay section 15 selectively located between the first latch section 11 and data output section 13 for delaying output data at the stage where output is supplied to the separate semiconductor chip 30.

The first latch section 11 on the semiconductor chip 10 latches output data to be output to the separate semiconductor chip 30 by a supplied clock signal and outputs the data. The clock output section 12 outputs a clock signal to the separate semiconductor chip 30. The data output section 13 outputs output data output from the first latch section 11 to the separate semiconductor chip 30.

The first delay section 14 is selectively located before the clock output section 12, delays a clock signal, and outputs it to the clock output section 12. The second delay section 15 is selectively located between the first latch section 11 and data output section 13, delays output data output from the first latch section 11, and outputs it to the data output section 13.

Both the first delay section 14 and second delay section 15 are located on the semiconductor chip 10 for testing the input characteristics of the separate semiconductor chip 30 about data output from the semiconductor chip 10. This input characteristic test will be made in, for example, a state in which the semiconductor integrated circuit 1 is formed on a wafer. These first delay section 14 and second delay section 15 are not used at a normal operation time after the test.

The separate semiconductor chip 30 is supplied with a clock signal and output data from the semiconductor chip 10. By latching by this clock signal, the separate semiconductor chip 30 imports the output data. If a data transfer frequency is increased in the case of a data input characteristic test being made, the influence of an error caused by a tester used in the test will become great. As a result, a setup/hold margin at the time of data being input to the separate semiconductor chip 30 cannot be measured accurately.

Therefore, if a setup/hold margin test is made, either the first delay section 14 or the second delay section 15 on the semiconductor chip 10 will be used. If a hold margin test is performed on the separate semiconductor chip 30, the first delay section 14 will be selected to delay a clock signal so that hold time at the time of inputting to the separate semiconductor chip 30 will shorten. This advances the timing with which the holding of output data input to the separate semiconductor chip 30 terminates, so the difference between the above hold time and the actual hold time narrows. As a result, operation performed when hold time is set strictly can be checked and a hold margin can be measured more accurately.

If a setup margin test is performed on the separate semiconductor chip 30, the second delay section 15 will be selected to delay output data so that setup time at the time of inputting to the separate semiconductor chip 30 will shorten. This delays the timing with which output data input to the separate semiconductor chip 30 is defined, so the difference between the above setup time and the actual setup time narrows. As a result, operation performed when setup time is set strictly can be checked and a setup margin can be measured more accurately.

Moreover, in the present invention, the semiconductor chip 10 includes clock input section 16 to which a clock signal output from the clock output section 12 is input again, data input section 17 to which input data is input from the separate semiconductor chip 30, second latch section 18 for latching this input data by a clock signal input from the clock input section 16, third delay section 19 selectively located between the clock input section 16 and the second latch section 18 for delaying a clock signal from the clock input section 16, and fourth delay section 20 selectively located between the data input section 17 and the second latch section 18 for delaying input data at the stage where input from the separate semiconductor chip 30 is accepted.

A clock signal output from the clock output section 12 is input again to the clock input section 16. Input data from the separate semiconductor chip 30 is input to the data input section 17. The second latch section 18 latches input data from the data input section 17 by a clock signal from the clock input section 16.

The third delay section 19 is selectively located between the clock input section 16 and the second latch section 18, delays a clock signal from the clock input section 16, and outputs it to the second latch section 18. The fourth delay section 20 is selectively located between the data input section 17 and the second latch section 18, delays input data from the data input section 17, and outputs it to the second latch section 18.

Both the third delay section 19 and fourth delay section 20 are located on the semiconductor chip 10 for testing the input characteristics of the second latch section 18 about data output from the separate semiconductor chip 30. The third delay section 19 and fourth delay section 20 are not used at a normal operation time after the test.

If a data transfer frequency is increased in the case of an input characteristic test being performed on the second latch section 18, the influence of an error caused by a tester used in the test will become great. As a result, a setup/hold margin at the time of the second latch section 18 latching cannot be measured accurately. This is the same with the above input characteristic test performed on the separate semiconductor chip 30.

If a hold margin test is performed on the second latch section 18, the third delay section 19 will be selected to delay a clock signal from the clock input section 16 so that hold time at the time of the second latch section 18 latching will shorten. This advances the timing with which the holding of input data input to the second latch section 18 terminates, so the difference between the above hold time and the actual hold time narrows. As a result, a hold margin can be measured more accurately.

If a setup margin test is performed on the second latch section 18, the fourth delay section 20 will be selected to delay input data so that setup time at the time of the second latch section 18 latching will shorten. This delays the timing with which input data input to the second latch section 18 is settled, so the difference between the above setup time and the actual setup time narrows. As a result, a setup margin can be measured more accurately.

As stated above, when the data input-output characteristics of the semiconductor chip 10 and separate semiconductor chip 30 are tested, a setup/hold margin can be measured accurately even if a data transfer frequency is increased. Therefore, proper data input-output operation will be guaranteed even if, for example, power supply voltage or ambient temperature varies. Moreover, mounting this semiconductor chip 10 in the semiconductor integrated circuit 1 enables defective products without a setup/hold margin to be rejected reliably at the test stage.

Now, embodiments of a semiconductor integrated circuit according to the present invention will be described. The following descriptions will be given with a logic chip and SDRAM as examples of semiconductor chips which are mounted in a semiconductor integrated circuit according to the present invention and which are connected by closed signal lines. Input-output characteristic tests for writing and reading data between these logic chip and SDRAM will be described.

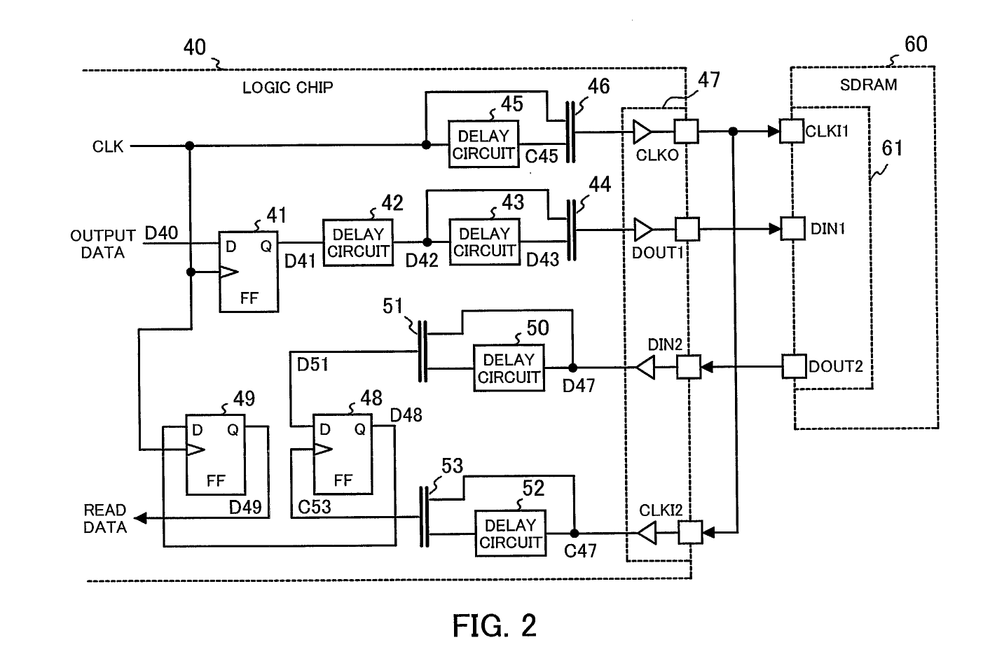

FIG. 2 shows the structure of a first embodiment of the present invention.

FIG. 2 shows the schematic structure of a data input-output block on a logic chip 40 which exchanges data with an SDRAM 60. The data input-output block on the logic chip 40 includes an FF 41 for latching data to be transferred to the SDRAM 60 with the rise timing of a clock signal from the inside, delay circuits 42 and 43 for delaying a signal output from the FF 41, a selection section 44 for selecting the delay circuit 43, a delay circuit 45 for delaying a clock signal, a selection section 46 for selecting the delay circuit 45, an input-output section 47 for accepting data and a clock signal from and outputting data and a clock signal to the SDRAM 60, an FF 48 for latching data transferred from the SDRAM 60 by an input clock signal, an FF 49 for latching data output from the FF 48 by a clock signal from the inside, a delay circuit 50 for delaying an input clock signal, a selection section 51 for selecting the delay circuit 50, a delay circuit 52 for delaying data transferred from the SDRAM 60, and a selection section 53 for selecting the delay circuit 52. The SDRAM 60 includes an input-output section 61 for accepting an input clock signal and data and outputting data.

The FF 41 accepts input control data, such as commands, addresses, and data to be written into the SDRAM 60, and latches this control data with the rise timing of a clock signal from the inside of the logic chip 40. The delay circuit 42 delays data output from the FF 41 at the time of control data transferred from the logic chip 40 being input to the SDRAM 60 so that hold time at the next rise of a clock signal will be satisfied.

As described later, if a setup margin test is performed on the SDRAM 60 at the time of data being input, the delay circuit 43 will be selected by the selection section 44 and delay data output from the delay circuit 42. As described later, the delay circuit 45 is selected by the selection section 46 to perform a hold margin test at the time of data being input to the SDRAM 60 and delays a clock signal.

The input-output section 47 outputs data output from the selection section 44 to the SDRAM 60 and accepts data read from the SDRAM 60. In addition, the input-output section 47 outputs a clock signal from the inside of the logic chip 40 to the SDRAM 60 and inputs it again to the logic chip 40.

The delay circuit 50 is supplied with data, which was read from the SDRAM 60 and which was input to the input-output section 47, is selected by the selection section 51 to perform a setup margin test at the time of the FF 48 latching this data, and delays the input data. This will be described later. The delay circuit 52 accepts a clock signal input from the input-output section 47, is selected by the selection section 53 to perform a hold margin test at the time of the FF 48 latching data read from the SDRAM 60, and delays the input clock signal. This will be described later.

The FF 48 latches data supplied from the selection section 51 by a clock signal from the selection section 53. The FF 49 latches data supplied from the FF 48 by a clock signal from the inside of the logic chip 40 and outputs the data.

A delay element consisting of a plurality of inverters or buffers connected in series, a delay element consisting of a combination of selectors, or the like will be used as each of the delay circuits 42, 43, 45, 50, and 52 located on the logic chip 40.

Various pieces of control data, such as commands, addresses, and data to be written, and a clock signal are input to the input-output section 61 on the SDRAM 60. Control data will be imported in synchronization with this clock signal and data will be written into a specified address.

On the SDRAM 60, input data is read in compliance with a read instruction and is output from the input-output section 61. In this case, the SDRAM 60 synchronizes read data by a clock signal input from the logic chip 40, delays the read data so that hold time for the FF 48 on the logic chip 40 will be satisfied, and outputs the read data. If the SDRAM 60 does not delay data, then a delay circuit which can give the same delay time may be located between the input-output section 47 and the delay circuit 50 or selection section 51 on the logic chip 40.

In FIG. 2, to simplify the descriptions, it is assumed that data is transferred over data buses only in one direction.

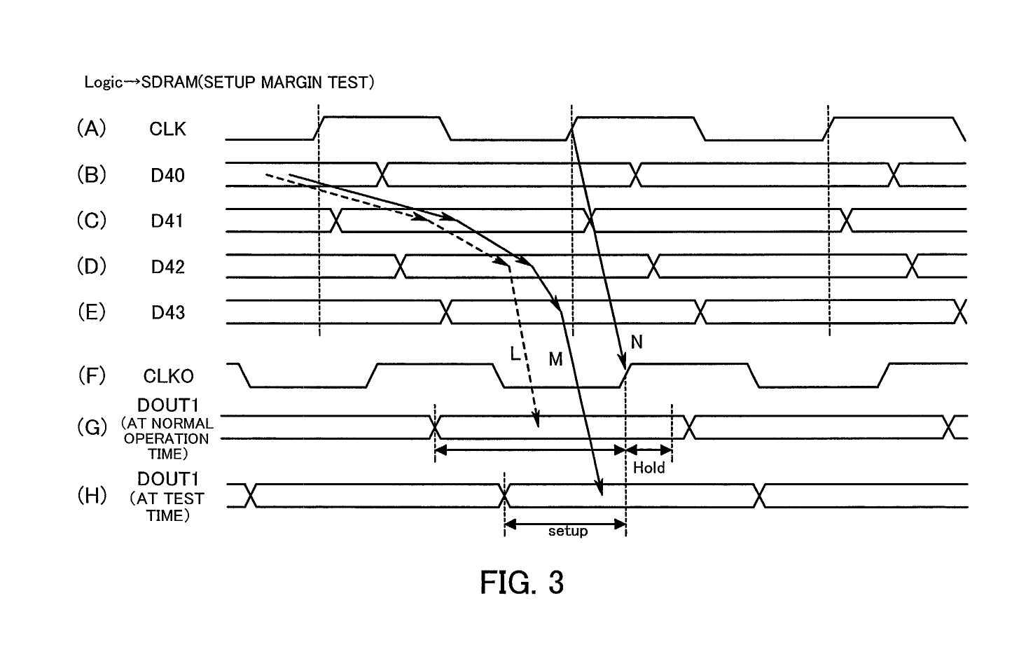

Now, operation in a setup/hold margin test performed between the logic chip 40 and SDRAM 60 will be described by comparison with normal operation. FIG. 3 is a time chart for describing operation in a setup margin test performed in the case of data being written into the SDRAM 60.

In FIG. 3, a dashed arrow L, solid arrow M, and solid arrow N indicate the movement of written data at a normal operation time, the movement of written data at a test time, and the movement of the rise timing of a clock signal at a test time and normal operation time respectively.

Data D40 shown in FIG. 3(B) is written data output from the logic chip 40 to the SDRAM 60. The FF 41 latches the data D40 with the rise timing of a clock signal CLK from the inside as shown in FIG. 3(A) and data D41 shown in FIG. 3(C) is output from the FF 41. The delay circuit 42 delays the data D41 so that hold time will be satisfied in the case of output data being latched with the next rise timing of the clock signal and being imported to the SDRAM 60. As a result, the delay circuit 42 outputs data D42 shown in FIG. 3(D).

At a normal operation time after the test, the delay circuits 43 and 45 are bypassed by the selection sections 44 and 46 respectively and the clock signal CLK and the data D42 output from the delay circuit 42 are output to the SDRAM 60 via the input-output section 47. Data DOUT1 output at this time is shown in FIG. 3(G) and satisfies hold time for the SDRAM 60 for the next rise timing of an output clock signal CLKO shown in FIG. 3(F).

Delay time by the delay circuit 42 is set in advance with tester errors which will occur on both of the logic chip 40 and SDRAM 60 at the time of measuring a waveform included so that the output data DOUT1 will fully satisfy hold time. However, if a setup/hold margin test is performed on the SDRAM 60, data transfers between the logic chip 40 and SDRAM 60 of a high frequency will increase the influence of a tester error on setup/hold time. As a result, a margin cannot be measured accurately.

Therefore, if a setup margin test is made, the delay circuit 43 is selected by the selection section 44 to further delay the data D42 output from the delay circuit 42. Data D43 output from the delay circuit 43 is shown in FIG. 3(E) and data DOUT1 output from the input-output section 47 is shown in FIG. 3(H). The data DOUT1 shown in FIG. 3(H) is delayed by the delay circuit 43 so that the timing with which the data is defined will be brought close to the rise timing of the clock signal CLKO, that is to say, so that setup time will shorten. As a result, data transfer operation in the case of setup time being shortened can be verified and a setup margin for the SDRAM 60 can be measured more accurately.

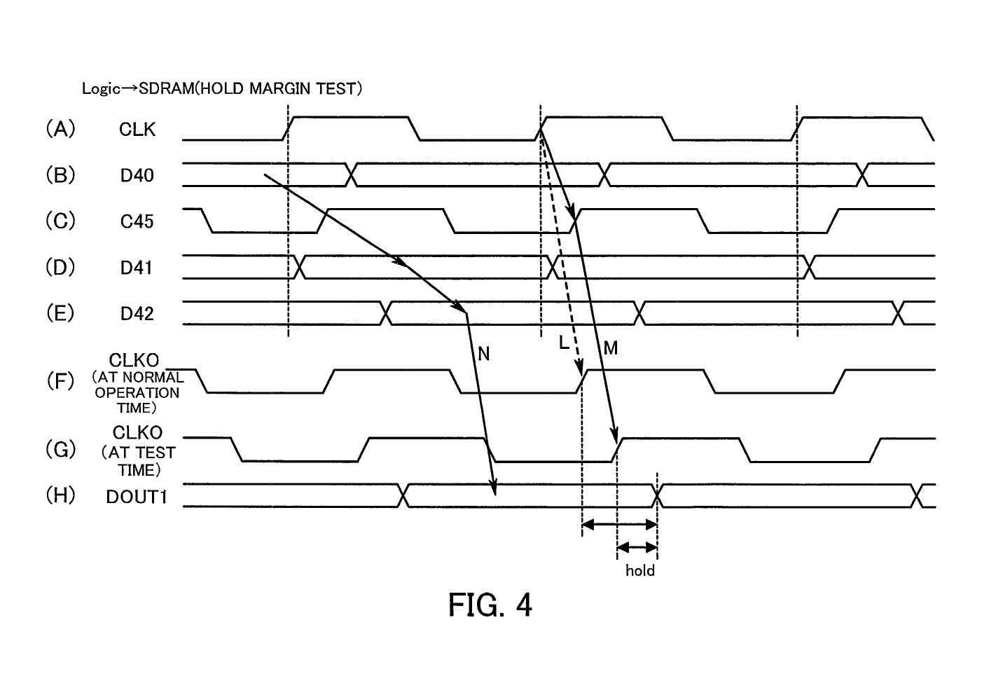

FIG. 4 is a time chart for describing operation in a hold margin test performed in the case of data being written into the SDRAM 60.

In FIG. 4, a dashed arrow L, solid arrow M, and solid arrow N indicate the movement of the rise timing of a clock signal at a normal operation time, the movement of the rise timing of a clock signal at a test time, and the movement of written data at a test time and normal operation time respectively.

Data DOUT1 output at a normal operation time from the input-output section 47 as shown in FIG. 4(H) is delayed by the delay circuit 42 so that hold time for the SDRAM 60 will be satisfied for the rise timing of a clock signal CLKO shown in FIG. 4(F). This is the same with the operation in FIG. 3. As stated above, however, delay time in the delay circuit 42 is set with tester errors included. Therefore, if a data transfer frequency is increased, it is difficult to measure a hold margin accurately.

Accordingly, if a hold margin test is performed on the SDRAM 60, the delay circuit 45 is selected by the selection section 46 to delay a clock signal CLK from the inside. Data C45 output from the delay circuit 45 is shown in FIG. 4(C) and a clock signal CLKO output from the input-output section 47 is shown in FIG. 4(G). The clock signal CLKO is delayed in this way and is output, so the data DOUT1 shown in FIG. 4(H) will be output prior to the clock signal CLKO. Therefore, the clock signal CLKO is delayed so that the timing with which the holding of the data terminates will be brought close to the rise timing of the clock signal CLKO, that is to say, so that hold time will shorten. As a result, data transfer operation in the case of hold time being shortened can be verified and a hold margin for the SDRAM 60 can be measured more accurately.

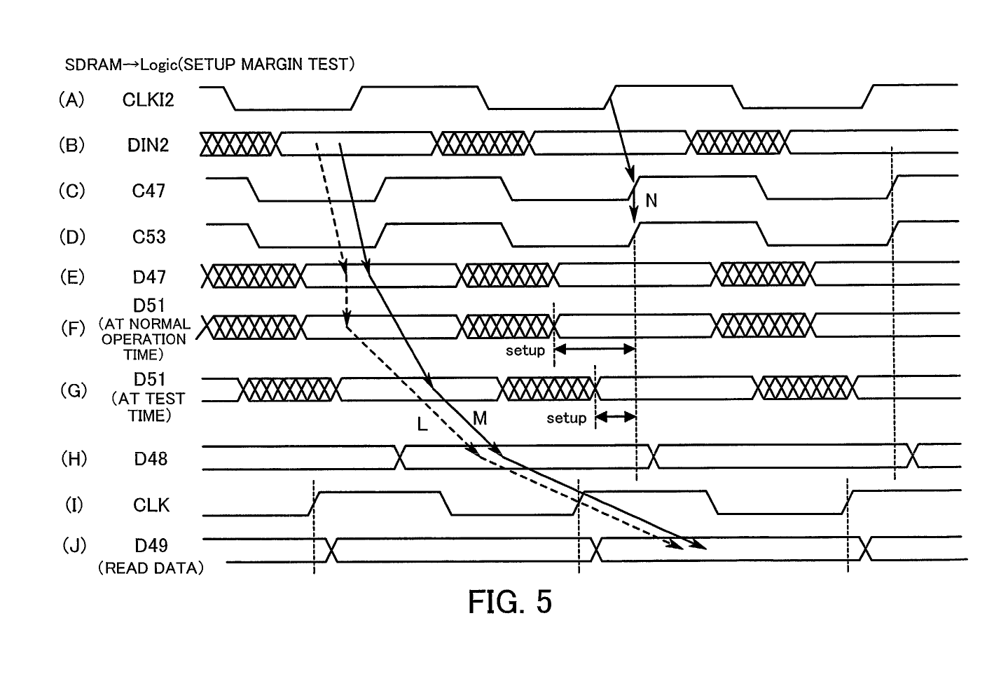

FIG. 5 is a time chart for describing operation in a setup margin test performed in the case of data being read from the SDRAM 60.

In FIG. 5, a dashed arrow L, solid arrow M, and solid arrow N indicate the movement of read data at a normal operation time, the movement of read data at a test time, and the movement of the rise timing of a clock signal at a test time and normal operation time respectively.

A clock signal CLKI2 shown in FIG. 5(A) is a clock signal CLKO which was output from inside the logic chip 40 and which was input again to the logic chip 40. By latching data from the SDRAM 60 by the use of this clock signal CLKI2, a delay in signal transmission caused by a buffer included in the input-output section 47 on the logic chip 40 can be canceled.

Data DIN2 shown in FIG. 5(B) is read data output from the SDRAM 60. The data DIN2 is latched by a clock signal CLKI1 input from the logic chip 40 to the SDRAM 60 and is output. Then the data DIN2 is delayed by the FF 48 on the logic chip 40 so that hold time will be satisfied, and is output. And then the data DIN2 is input to the input-output section 47 on the logic chip 40.

At a time when the normal operation of reading data from the SDRAM 60 is performed, the delay circuits 50 and 52 are bypassed by the selection sections 51 and 53 respectively. In this case, a clock signal C53 shown in FIG. 5(D) is input from the selection section 53 to the FF 48 and data D51 shown in FIG. 5(F) is input from the selection section 51 to the FF 48. The FF 48 latches the input data D51 with the rise timing of the clock signal C53 and outputs data D48 shown in FIG. 5(H) to the FF 49. The FF 49 is supplied with a clock signal CLK from the inside of the logic chip 40 as shown in FIG. 5(I), latches the data D48 with the rise timing of this clock signal CLK, and outputs data D49 shown in FIG. 5(J) as data read from the SDRAM 60.

A setup/hold margin at the time of data being input to the FF 48 is set with tester errors included. This is the same with writing into the SDRAM 60 as described above. Therefore, if an operation test for latching by the FF 48 is performed, it is difficult to measure a hold margin accurately with a transfer frequency increased.

Accordingly, if a setup margin test is performed on the FF 48, the delay circuit 50 is selected by the selection section 51 to delay data D47 input from the input-output section 47. The data D51 output from the delay circuit 50 via the selection section 51 at this time is shown in FIG. 5(G). The data D51 shown in FIG. 5(G) is delayed by the delay circuit 50 so that the timing with which the data is defined will be brought close to the rise timing of the clock signal C53, that is to say, so that setup time will shorten. As a result, data transfer operation in the case of setup time being shortened can be verified and a setup margin for the logic chip 40 can be measured more accurately.

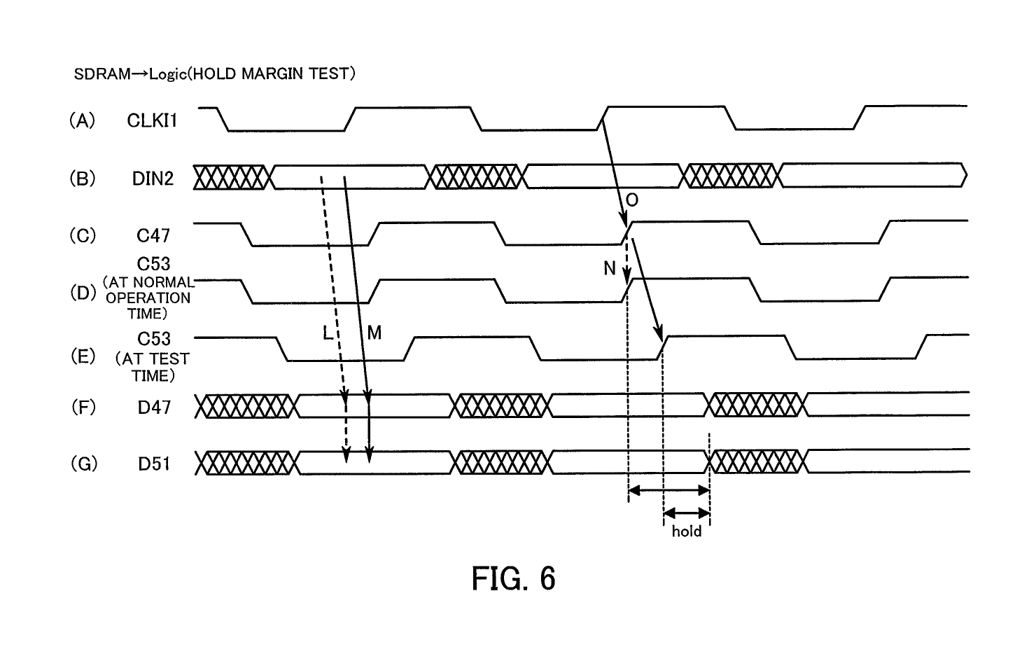

FIG. 6 is a time chart for describing operation in a hold margin test performed in the case of data being read from the SDRAM 60.

In FIG. 6, a dashed arrow L, solid arrow M, dashed line N, and solid arrow O indicate the movement of written data at a normal operation time, the movement of written data at a test time, the movement of the rise timing of a clock signal at a normal operation time, and the movement of the rise timing of a clock signal at a test time respectively.

At a normal operation time, the delay circuits 50 and 52 are not selected and data D51 shown in FIG. 6(G) and a clock signal C53 shown in FIG. 6(D) are supplied to the FF 48. This is the same with the operation in FIG. 5. As stated above, a hold margin at the time of data being input to the FF 48 is set with tester errors included. Therefore, if an operation test for latching by the FF 48 is performed, it is difficult to measure a hold margin accurately with a transfer frequency increased.

Accordingly, if a hold margin test is performed on the FF 48, the delay circuit 52 is selected by the selection section 53 to delay a clock signal C47 input from the input-output section 47. A clock signal C53 output from the delay circuit 52 via the selection section 53 at this time is shown in FIG. 6(E). The clock signal C53 is delayed in this way and is output, so the data D51 shown in FIG. 6(G) will be input to the FF 48 prior to the clock signal C53. Therefore, the clock signal C53 is delayed so that the timing with which the holding of the data terminates will be brought close to the rise timing of the clock signal C53, that is to say, so that hold time will shorten. As a result, data transfer operation in the case of hold time being shortened can be verified and a hold margin for the logic chip 40 can be measured more accurately.

As described above, the delay circuit 43, 45, 50, and 52 used for performing a setup/hold margin test are selectively located on the logic chip 40. At a test time one of them will be selected for use. As a result, even if a data transfer frequency is increased, a setup/hold margin at the time of writing and reading data between the logic chip 40 and the SDRAM 60 in the same package connected thereto by closed signal lines can be measured accurately. Therefore, proper data writing and reading operation will be guaranteed even if, for example, power supply voltage or ambient temperature varies. Moreover, with semiconductor integrated circuits, such as MCMs or MCPs, in which these logic chip 40 and SDRAM 60 are mounted, defective products without a setup/hold margin can be rejected reliably at the test stage.

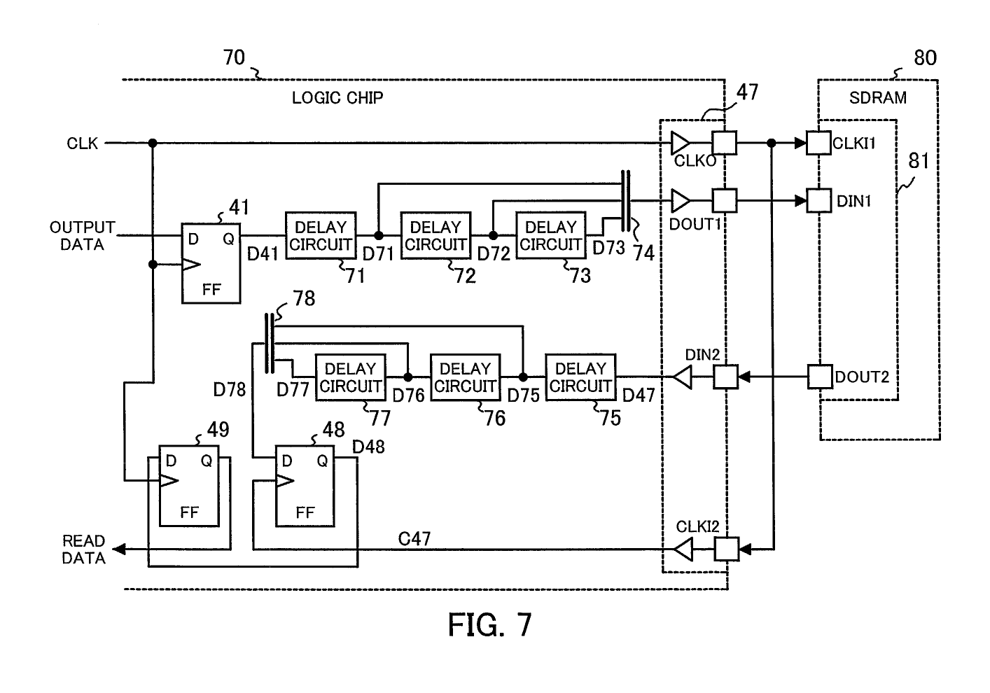

In the first embodiment described above, a delay circuit is used for delaying either data or a clock signal when a setup/hold margin test is made. However, delay time only for data may be changed. Now, the structure of such a semiconductor chip will be described. FIG. 7 is a view showing the structure of a second embodiment of the present invention. In FIG. 7, functional blocks corresponding to those in FIG. 2 will be marked with the same symbols and descriptions of them will be omitted.

FIG. 7 shows the schematic structure of a data input-output block on a logic chip 70 which exchanges data with an SDRAM 80. The data input-output block on the logic chip 70 includes an FF 41 for latching data to be transferred to the SDRAM 80 by a clock signal from the inside, delay circuits 71, 72, and 73 for delaying a signal output from the FF 41, a selection section 74 for selecting the delay circuits 72 and 73, an input-output section 47 for accepting data and a clock signal from and outputting data and a clock signal to the SDRAM 80, an FF48 for latching data transferred from the SDRAM 80 by an input clock signal, an FF 49 for latching data output from the FF 48 by a clock signal from the inside, delay circuits 75, 76, and 77 for delaying data transferred from the SDRAM 80, and a selection section 78 for selecting the delay circuits 76 and 77. The SDRAM 80 includes an input-output section 81 for accepting an input clock signal and data and outputting data.

At a normal operation time when data is transferred from the logic chip 70 to the SDRAM 80, the delay circuit 72 is selected by the selection section 74 and data output from the FF 41 is delayed by the delay circuits 71 and 72. The total of delay time in the delay circuits 71 and 72 is set at the time of data transferred from the logic chip 70 being input to the SDRAM 80 so that hold time at the next rise of a clock signal will be satisfied.

At a time when a setup margin test is performed in the case of data being input to the SDRAM 80, both the delay circuits 72 and 73 are selected by the selection section 74 and data output from the FF 41 is delayed by the delay circuits 71, 72, and 73. At a time when a hold margin test is performed in the case of data being input to the SDRAM 80, the delay circuits 72 and 73 are bypassed by the selection section 74 and data output from the FF 41 is delayed only by the delay circuit 71.

On the other hand, at a normal operation time when data is read from the SDRAM 80, the delay circuit 76 is selected by the selection section 78 and data sent from the input-output section 47 is delayed by the delay circuits 75 and 76. Delay time by the delay circuits 75 and 76 is set at the time of data being latched by the FF 48 so that hold time at the next rise of a clock signal sent from the input-output section 47 will be satisfied.

At a time when a setup margin test is performed on the FF 48, the delay circuits 76 and 77 are selected by the selection section 78 and data sent from the input-output section 47 is delayed by the delay circuits 75, 76, and 77. At a time when a hold margin test is performed on the FF 48, the delay circuits 76 and 77 are bypassed by the selection section 78 and data sent from the input-output section 47 is delayed only by the delay circuit 75.

Various pieces of control data, such as commands, addresses, and data to be written, and a clock signal are input to the input-output section 81 on the SDRAM 80. Control data will be imported in synchronization with this clock signal and data will be written into a specified address. On the SDRAM 80, input data is read in compliance with a read instruction and is output from the input-output section 81 in synchronization with a clock signal input from the logic chip 70. Unlike the case of the above first embodiment, a delay for satisfying hold time for the FF 48 on the logic chip 70 will not be given to output data.

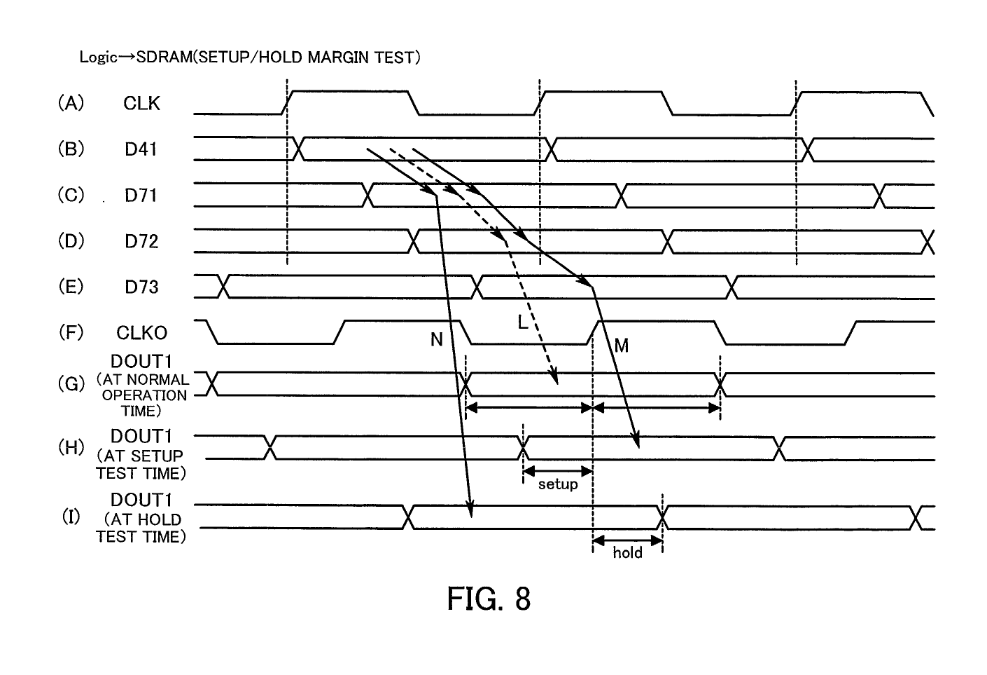

Now, operation in a setup/hold margin test performed between the logic chip 70 and SDRAM 80 will be described by comparison with normal operation. FIG. 8 is a time chart for describing operation in a setup/hold margin test performed in the case of data being written into the SDRAM 80.

In FIG. 8, a dashed arrow L, solid arrow M, and solid arrow N indicate the movement of data at a normal operation time, at the time of a setup margin test being performed on the SDRAM 80, and at the time of a hold margin test being performed on the SDRAM 80 respectively.

At a normal operation time when data is transferred to the SDRAM 80, the delay circuit 72 is selected by the selection section 74 and the delay circuit 73 is bypassed by the selection section 74. That is to say, data D41 latched by the FF 41 with the rise timing of a clock signal as shown in FIG. 8(B) is delayed by the delay circuits 71 and 72. As a result, data D72 shown in FIG. 8(D) is obtained. Data DOUT1 output from the input-output section 47 to the SDRAM 80 is shown in FIG. 8(G) and has been delayed by both the delay circuits 71 and 72 so that hold time for the SDRAM 80 will be satisfied at the next rise timing of a clock signal CLKO shown in FIG. 8(F). How delay time is divided between the delay circuits 71 and 72 will be set with a hold margin to be tested taken into consideration.

At a time when a setup margin test is performed on the SDRAM 80, both the delay circuits 72 and 73 are selected by the selection section 74 and data output from the FF 41 is delayed by the delay circuits 71, 72, and 73. As a result, data D73 shown in FIG. 8(E) is obtained. Data DOUT1 output from the input-output section 47 is shown in FIG. 8(H). Inserting the delay circuit 73 brings the timing with which the data is defined close to the rise timing of a clock signal CLKO in comparison to the data DOUT1 shown in FIG. 8(G) (at a normal operation time). As a result, data transfer operation in the case of setup time being shortened can be verified.

At a time when a hold margin test is performed on the SDRAM 80, both the delay circuits 72 and 73 are bypassed by the selection section 74 and data is delayed only by the delay circuit 71. In this case, data 71 output from the delay circuit 71 is shown in FIG. 8(C). Data DOUT1 output from the input-output section 47 is shown in FIG. 8(I). The delay time in the delay circuit 72 is removed from the normal operation state, so the data will be output prior to a clock signal CLKO. Therefore, when the data is imported to the SDRAM 80, the timing with which the holding of the data terminates will be brought close to the rise timing of the clock signal CLKO. As a result, data transfer operation in the case of hold time being shortened can be verified.

As stated above, in the second embodiment, delay time in two delay circuits inserted in advance so that hold time for the SDRAM 80 will be satisfied at a normal operation time is divided and one of the two delay circuits is removed at the time of a hold margin test being made. By doing so, a test can be made with hold time shortened. In the above first embodiment, however, data is output prior to a clock signal by delaying the clock signal.

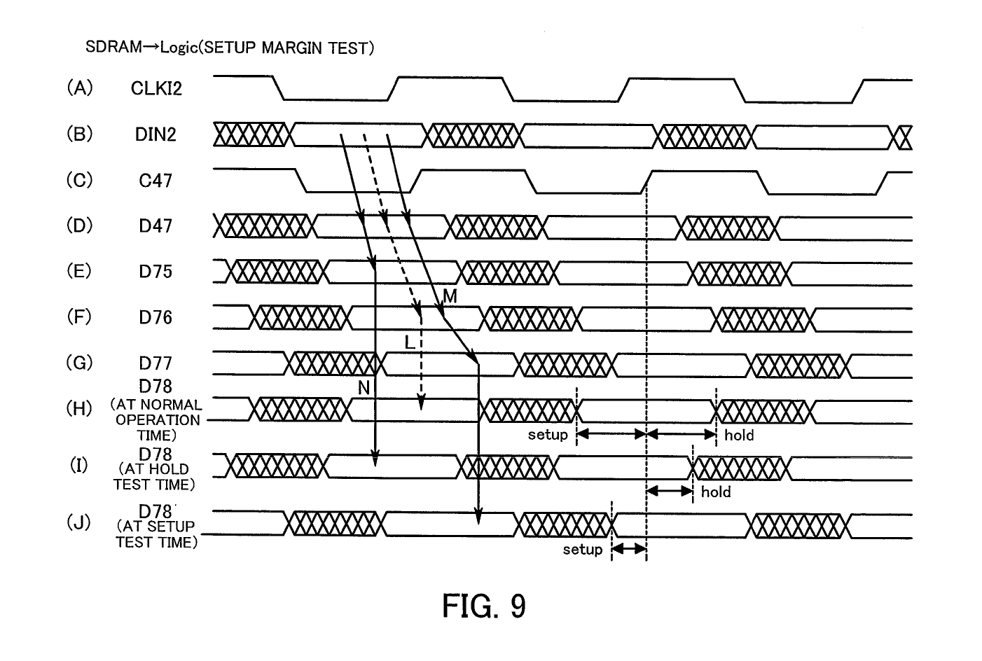

FIG. 9 is a time chart for describing operation in a setup/hold margin test performed in the case of data being read from the SDRAM 80.

In FIG. 9, a dashed arrow L, solid arrow M, and solid arrow N indicate the movement of read data at a normal operation time, at the time of a setup margin test being performed on the FF 48 on the logic chip 70, and at the time of a hold margin test being performed on the FF 48 on the logic chip 70 respectively.

A clock signal CLK shown in FIG. 9(A) is a clock signal CLKO which was output from inside the logic chip 70 and which was input again to the logic chip 70. This clock signal CLK is used for canceling a delay in signal transmission caused by a buffer included in the input-output section 47 on the logic chip 70.

Data DIN2 shown in FIG. 9(B) is data which is read from the SDRAM 80 and which is input to the input-output section 47 on the logic chip 70. Unlike the case of the above first embodiment, a delay for satisfying hold time for the FF 48 on the logic chip 70 will not be given to this data on the SDRAM 80.

At a normal operation time when data read from the SDRAM 80 is input, the delay circuit 76 is selected by the selection section 78 and the delay circuit 77 is bypassed by the selection section 78. That is to say, data D47 output from the input-output section 47 as shown in FIG. 9(D) is delayed by the delay circuits 75 and 76. As a result, data D76 shown in FIG. 9(F) is obtained. Data D78 input from the selection section 78 to the FF 48 is shown in FIG. 9(H) and has been delayed by both the delay circuits 75 and 76 so that hold time for the FF 48 will be satisfied at the next rise timing of a clock signal C47 shown in FIG. 9(C). How delay time is divided between the delay circuits 75 and 76 will be set with a hold margin to be tested taken into consideration.

At a time when a setup margin test is performed on the FF 48, both the delay circuits 76 and 77 are selected by the selection section 78 and data is delayed by the delay circuits 75, 76, and 77. As a result, data D77 shown in FIG. 9(G) is obtained. Data D78 input to the FF 48 is shown in FIG. 9(J). Inserting the delay circuit 77 brings the timing with which the data is defined close to the rise timing of a clock signal C47 in comparison to the data D78 shown in FIG. 9(H) (at a normal operation time). As a result, data transfer operation in the case of setup time being shortened can be verified.

At a time when a hold margin test is performed on the FF 48, both the delay circuits 76 and 77 are bypassed by the selection section 78 and data is delayed only by the delay circuit 75. In this case, data D75 output from the delay circuit 75 is shown in FIG. 9(E). Data D78 input to the FF 48 is shown in FIG. 9(I). The delay time in the delay circuit 76 is removed from the normal operation state, so the data will be output prior to a clock signal C47. Therefore, the timing with which the holding of the data input to the FF 48 terminates will be brought close to the rise timing of the clock signal C47. As a result, data transfer operation in the case of hold time being shortened can be verified.

As stated above, delay time in two delay circuits inserted in advance so that hold time for the FF 48 will be satisfied at a normal operation time is divided and one of the two delay circuits is removed at the time of a hold margin test being performed on the FF 48 on the logic chip 70. This is the same with the test performed on the SDRAM 80. By doing so, a test can be made with hold time shortened.

By the way, in the above first and second embodiments, the delay circuits inserted for performing a setup/hold margin test should not be selected except at a test time. It therefore is preferable that actual semiconductor chips should have the function of being able to switch the operation of a selection section for selecting each of delay circuits used for performing the test by a signal from the outside.

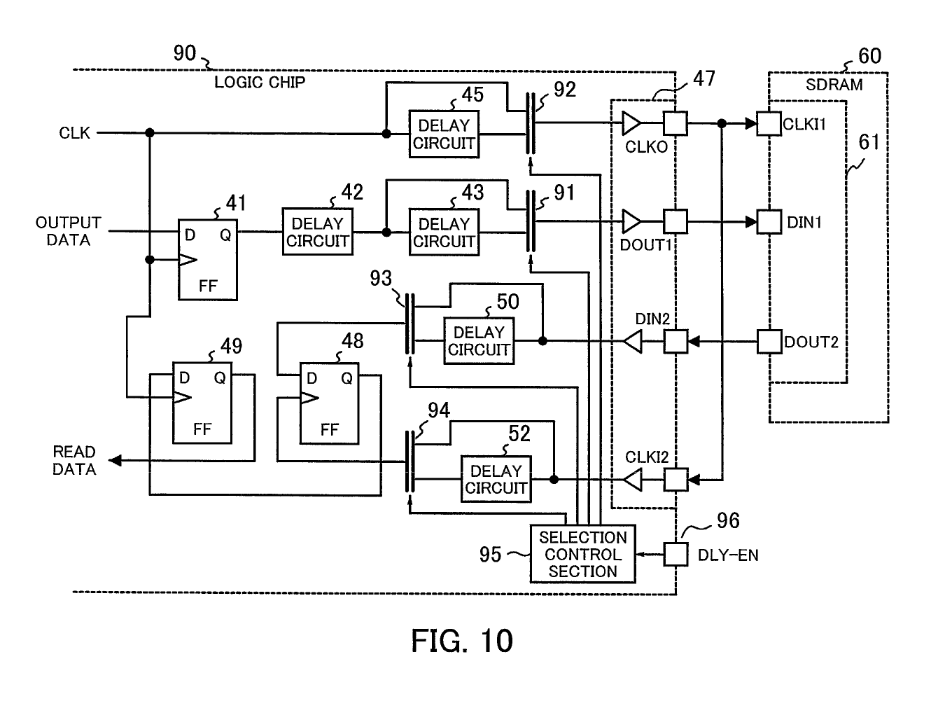

Now, an embodiment which has the function of switching the operation of a selection section will be described. FIG. 10 is a view showing the structure of a third embodiment of the present invention.

In this example, the function of switching the operation of the selection sections for selecting the delay circuits used for performing a setup/hold margin test is added to the circuit structure of the first embodiment shown in FIG. 2. In FIG. 10, functional blocks corresponding to those in FIG. 2 will be marked with the same symbols and descriptions of them will be omitted.

A logic chip 90 shown in FIG. 10 includes a selection control section 95 for controlling the operation of selection sections 91, 92, 93, and 94 for selecting delay circuits 43, 45, 50, and 52 respectively and an input terminal 96 for inputting a control signal from the outside to the selection control section 95.

For example, a select enable signal DLY-EN for specifying whether to enable the use of all the delay circuits 43, 45, 50, and 52 will be input to the input terminal 96. While a select enable signal DLY-EN is not inputting, the selection control section 95 controls the operation of the selection sections 91 through 94 so that the delay circuits 43, 45, 50, and 52 will not be selected. This function enables the function of each of delay circuits used for performing a setup/hold margin test to be always canceled except at the time of performing the test.

Moreover, select and non-select for each delay circuit may be switched according to the logic level of a control signal input to the input terminal 96. For example, many of ordinary semiconductor chips have an input terminal for specifying a test mode and this input terminal needs to be always clipped at a test time. Therefore, this input terminal may also be used as the input terminal 96 for specifying select and non-select for a delay circuit.

Furthermore, if the logic chip 90 includes a common path to a processor, a register for sending a control signal under the control of this processor to freely switch select or non-select for each delay circuit may be located. In this case, for example, the register will hold data for specifying the operation of each delay circuit at an address specified by the processor and this data will become effective while a select enable signal DLY-EN is inputting from the input terminal 96.

In the above third embodiment, descriptions of the example in which the function of switching the operation of the selection sections is added to the structure of the first embodiment shown in FIG. 2 have been given. However, the function of switching the operation of each selection section may be added to the structure of the second embodiment shown in FIG. 7.

In the above first, second, and third embodiments, the delay circuits are located to fully satisfy hold time for the SDRAM at a normal operation time when data is transferred from the logic chip to the SDRAM. This delay is given by, for example, the delay circuit 42 in the first embodiment shown in FIG. 2 or the delay circuits 71 and 72 in the second embodiment shown in FIG. 7.

However, if a data transfer frequency is high, a clock signal and data from the inside of the logic chip will be delayed by transmission lines, input-output buffers, etc. while being transferred to the SDRAM, and, in many cases, they will differ in delay time. For example, usually data is delayed more than a clock signal. If there is such a difference in delay time between a clock signal and data, transferred data does not necessarily satisfy hold time for the SDRAM as designed.

Therefore, with the circuit structure in the above first and second embodiments, difference in delay time between a clock signal and data may be compensated by comparing a clock signal which was output from the input-output section and which was input again and a clock signal from the inside and by controlling delay time in the delay circuit to satisfy hold time for the SDRAM.

Data read from the SDRAM is once latched by a clock signal which was output from the logic chip and which was input again. If a frequency is high, a clock signal may be delayed significantly on the transmission lines after being input again to the logic chip and before being input to the FF where latching is performed. Therefore, the phase of a clock signal input to the FF may be adjusted by comparing the clock signal which has just been input again and data latched by the FF.

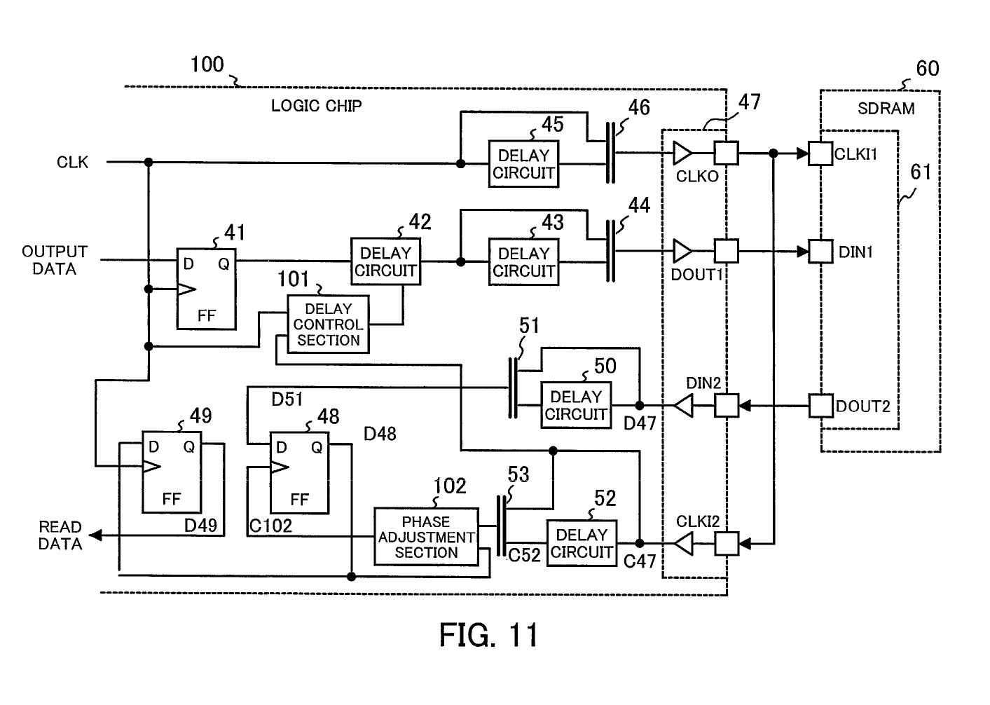

Now, an embodiment in which control over delay time for transferred data and adjustment in the phase of a clock signal described above are performed will be described. FIG. 11 is a view showing the structure of a fourth embodiment of the present invention.

In FIG. 11, a delay control section 101 for controlling delay time for data transferred to the SDRAM 60 and a phase adjustment section 102 for adjusting the phase of an input clock signal are added to the circuit structure in the first embodiment shown in FIG. 2. In FIG. 11, functional blocks corresponding to those in FIG. 2 will be marked with the same symbols and descriptions of them will be omitted.

The delay control section 101 on a logic chip 100 shown in FIG. 11 is supplied with a clock signal from the inside of the logic chip 100 and a clock signal which was once output and was input again from an input-output section 47, and controls delay time in a delay circuit 42. The phase adjustment section 102 is located between a selection section 53 and an FF 48, is supplied with a clock signal output from the selection section 53 and data output from the FF 48, and adjusts the phase of a clock signal output to the FF 48.

When data is transferred from the logic chip 100 to the SDRAM 60, delay time by transmission delay which will occur in a clock signal before the clock signal being output from the inside of the logic chip 100 to the SDRAM 60 via the input-output section 47 and delay time by transmission delay which will occur in data before the data being output from an FF 41 to the SDRAM 60 via the input-output section 47 may differ.

Therefore, if delay time for data is longer than delay time for a clock signal, for example, the delay control section 101 recognizes that a clock signal input again from the input-output section 47 will be input after a clock signal from the inside, and controls by shortening delay time in the delay circuit 42 so that the phase of the data will be advanced. In the example shown in FIG. 2, delay time in the delay circuit 42 is set in advance and is constant. In this example, however, this delay time is variable, so difference in phase between a clock signal and data transferred can be kept constant.

Actual data read from the SDRAM 60 consists of, for example, 32 or 64 bits, so a plurality of FFs 48 each corresponding to a bit will be located to latch this data. Therefore, a clock signal output from the selection section 46 will be distributed to the plurality of FFs 48 via a buffer or the like. As a result, significant delays will occur in this transmission process.

The phase adjustment section 102 compares the phase of a clock signal output from the selection section 53 near the input-output section 47 and that of data latched by a clock signal involving delay by the clock distribution and makes adjustment in order to advance the phase of the clock signal supplied to the FF 48 according to phase delay time for the latched data. This compensates difference in delay time between the clock signal and data supplied to the FF 48. As a result, a hold margin for the FF 48 can be secured stably.

Now, operation at the time of a setup/hold margin test being performed in the fourth embodiment will be described.

If data is transferred from the logic chip 100 to the SDRAM 60, signal waveforms at the time of a setup/hold margin test being performed on the SDRAM 60 is the same as those in the first embodiment shown in FIGS. 3 and 4, except that delay time in the delay circuit 42 will vary for optimization. When a setup/hold margin test is performed, first, delay time in the delay circuit 42 is adjusted by the delay control section 101 in a state in which both delay circuits 43 and 45 are bypassed, and adjusted delay time is maintained. Then the delay circuit 43 or 45 is selected to perform a test.

This is the same with a setup/hold margin test performed on the FF 48 on the logic chip 100 in the case of data being read from the SDRAM 60. That is to say, first, the phase of a clock signal supplied to the FF 48 is adjusted by the phase adjustment section 102 in a state in which both delay circuits 50 and 52 are bypassed, and an adjusted phase is maintained. Then the delay circuit 50 or 52 is selected to perform a test.

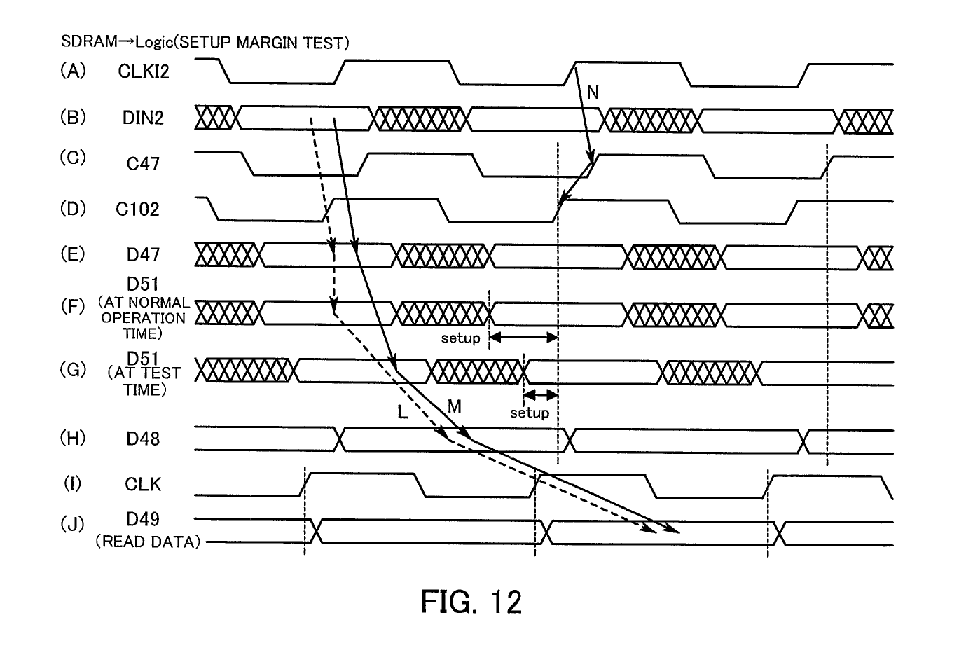

FIG. 12 is a time chart for describing operation in a setup margin test performed in the case of data being read from the SDRAM 60.

Signal waveforms shown in FIG. 12 differ from those in the first embodiment shown in FIG. 5 in that the phase of a clock signal C102 supplied to the FF 48 as shown in FIG. 12(D) is advanced by the function of the phase adjustment section 102 to a clock signal C47 from the input-output section 47 as shown in FIG. 12(C).

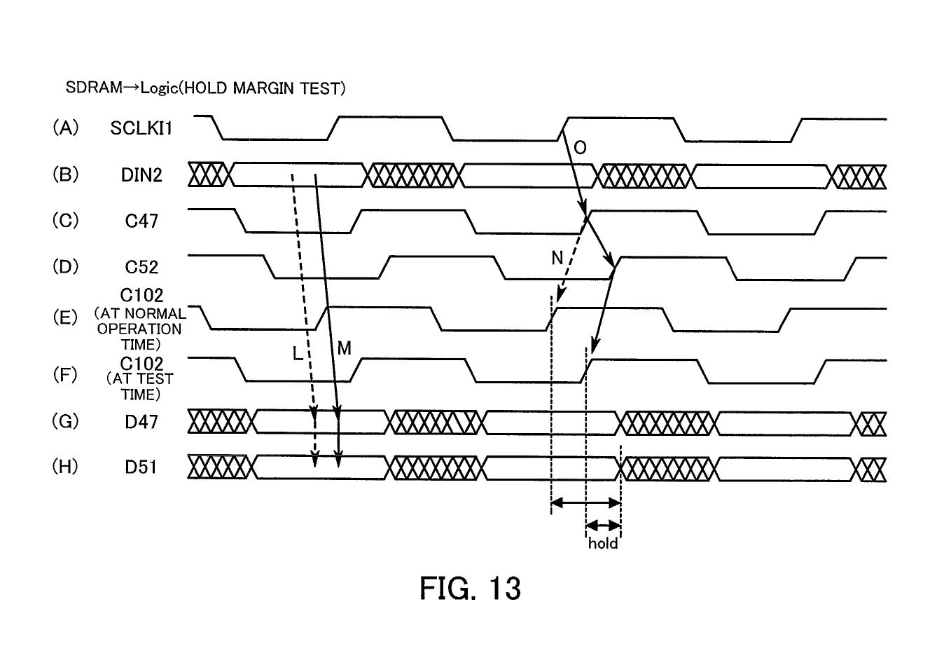

FIG. 13 is a time chart for describing operation in a hold margin test performed in the case of data being read from the SDRAM 60.

Signal waveforms shown in FIG. 13 differ from those in the first embodiment shown in FIG. 6 in that the phase of a clock signal C102 supplied to the FF 48 as shown in FIG. 13(E) is advanced to a clock signal C47 from the input-output section 47 as shown in FIG. 13(C) at a normal operation time and in that the phase of a clock signal C102 supplied to the FF 48 as shown in FIG. 13(F) is advanced to a clock signal C52 output from the delay circuit 52 as shown in FIG. 13(D) at a test time. Both these phase adjustments are performed by the phase adjustment section 102. The adjusted phase of a clock signal obtained by making such an adjustment at a normal operation time is also used in a hold margin test.

In the above fourth embodiment, functions for controlling delay time for data and the phase of a clock signal are added to the structure of the first embodiment shown in FIG. 2. However, these control functions can be added to, for example, the structure of the second embodiment shown in FIG. 7, the structure of the third embodiment shown in FIG. 10, or the structure in which the function of switching the operation of the selection sections as shown in FIG. 10 is added to the second embodiment.

For example, if these control functions are added to the structure of the second embodiment shown in FIG. 7, delay time in the delay circuit 71 will be controlled according to difference in phase between a clock signal from the inside of the logic chip 70 and a clock signal which was once output and was input again via the input-output section 47. Moreover, the phase of a clock signal output from the input-output section 47 to the FF 48 will be adjusted according to difference in phase between the clock signal input again via the input-output section 47 and data output from the FF 48.

As has been described in the foregoing, a semiconductor integrated circuit according to the present invention includes first delay section selected to perform a hold margin test in the case of transferring data from a semiconductor chip mounted in the semiconductor integrated circuit to a separate semiconductor chip mounted in the semiconductor integrated circuit for delaying a clock signal and second delay section selected to perform a setup margin test in the case of transferring data from the semiconductor chip to the separate semiconductor chip for delaying output data. By selecting each of these delay section, operation in the case of hold time or setup time for the separate semiconductor chip being shortened can be checked. Therefore, even if a data transfer frequency is increased, a setup/hold margin can be measured more accurately.

Furthermore, a semiconductor integrated circuit according to the present invention includes third delay section selected to perform a hold margin test on second latch section in the case of data being input from the separate semiconductor chip for delaying a clock signal from clock input section and fourth delay section selected to perform a setup margin test on the second latch section in the case of data being input from the separate semiconductor chip for delaying input data. By selecting each of these delay section, operation in the case of hold time or setup time for the second latch section being shortened can be checked. Therefore, even if a data transfer frequency is increased, a setup/hold margin can be measured more accurately.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A semiconductor integrated circuit in which a plurality of semiconductor chips are mounted in the same package, one of the plurality of semiconductor chips including:
a first latch section for latching output data to be output to a separate semiconductor chip of the plurality of semiconductor chips mounted in the same package by a clock signal;
a clock output section for outputting the clock signal to the separate semiconductor chip;
a data output section for outputting the output data output from the first latch section to the separate semiconductor chip;
a first delay section selectively located before the clock output section for delaying the clock signal; and
a second delay section selectively located between the first latch section and the data output section for delaying the output data,
wherein the first delay section is selected to perform a hold margin test at the time of the output data being input to the separate semiconductor chip and the second delay section is selected to perform a setup margin test at the time of the output data being input to the separate semiconductor chip.

2. The semiconductor integrated circuit according to claim 1, wherein the first delay section delays the clock signal so that hold time at the time of the output data being input to the separate semiconductor chip will shorten.

3. The semiconductor integrated circuit according to claim 1, wherein the second delay section delays the output data so that setup time at the time of the output data being input to the separate semiconductor chip will shorten.

4. The semiconductor integrated circuit according to claim 1, the semiconductor chip further including:
a clock input section to which the clock signal output from the clock output section is input again;
a data input section to which input data is input from the separate semiconductor chip;
a second latch section for latching the input data by the clock signal input from the clock input section;
a third delay section selectively located between the clock input section and the second latch section for delaying the clock signal from the clock input section; and
a fourth delay section selectively located between the data input section and the second latch section for delaying the input data,
wherein the third delay section is selected to perform a hold margin test on the second latch section and the fourth delay section is selected to perform a setup margin test on the second latch section.

5. The semiconductor integrated circuit according to claim 4, wherein the third delay section delays the clock signal from the clock input section so that hold time at the time of the second latch section latching the input data will shorten.

6. The semiconductor integrated circuit according to claim 4, wherein the fourth delay section delays the input data so that setup time at the time of the second latch section latching the input data will shorten.

7. The semiconductor integrated circuit according to claim 4, wherein select and non-select for the first, second, third, and fourth delay sections can be specified by a control signal which is input from the outside or which is output from an internal register.

8. The semiconductor integrated circuit according to claim 1, further including a fifth delay section located between the first latch section and the second delay section for delaying the output data output from the first latch section so that standards for hold time at the time of the output data being input to the separate semiconductor chip will be met at a normal operation time.

9. The semiconductor integrated circuit according to claim 8, the semiconductor chip further including a delay control section for controlling delay time in the fifth delay section on the basis of the clock signal supplied to the clock output section and the clock signal from the clock input section.

10. The semiconductor integrated circuit according to claim 1, the semiconductor chip further including a phase adjustment section for adjusting the phase of the clock signal supplied to the third delay section on the basis of the clock signal output from the clock input section or the third delay section and the input data output from the second latch section.

11. A semiconductor integrated circuit in which a plurality of semiconductor chips are mounted in the same package, one of the plurality of semiconductor chips including:
a first latch section for latching output data to be output to a separate semiconductor chip of the plurality of semiconductor chips mounted in the same package by a clock signal;
a clock output section for outputting the clock signal to the separate semiconductor chip;
a data output section for outputting the output data output from the first latch section to the separate semiconductor chip;
a first delay section located between the first latch section and the data output section for delaying the output data from the first latch section;
a second delay section selectively located between the first delay section and the data output section for delaying the output data from the first delay section; and
a third delay section selectively located between the second delay section and the data output section for delaying the output data from the second delay section,
wherein both the second and third delay sections are bypassed to perform a hold margin test at the time of the output data being input to the separate semiconductor chip,
wherein both the second and third delay sections are selected to perform a setup margin test at the time of the output data being input to the separate semiconductor chip, and
wherein, at a normal operation time, the second delay section is selected and the third delay section is bypassed.

12. The semiconductor integrated circuit according to claim 11, wherein delay time in the first and second delay sections is set so that standards for hold time at the time of the output data being input to the separate semiconductor chip will be met at a normal operation time.

13. The semiconductor integrated circuit according to claim 11, wherein the third delay section delays the output data so that setup time at the time of the output data being input to the separate semiconductor chip will shorten.

14. The semiconductor integrated circuit according to claim 11, wherein when both the second and third delay sections are bypassed, the output data is delayed so that hold time at the time of the output data being input to the separate semiconductor chip will shorten.

15. The semiconductor integrated circuit according to claim 11, the semiconductor chip further including:
a clock input section to which the clock signal output from the clock output section is input again;
a data input section to which input data is input from the separate semiconductor chip;
a second latch section for latching the input data by the clock signal input from the clock input section;
a fourth delay section located between the clock input section and the second latch section for delaying the input data from the data input section;
a fifth delay section selectively located between the fourth delay section and the second latch section for delaying the input data from the fourth delay section; and
a sixth delay section selectively located between the fifth delay section and the second latch section for delaying the input data from the fifth delay section,
wherein both the fifth and sixth delay sections are bypassed to perform a hold margin test on the second latch section,
wherein both the fifth and sixth delay sections are selected to perform a setup margin test on the second latch section, and
wherein, at a normal operation time, the fifth delay section is selected and the sixth delay section is bypassed.

16. The semiconductor integrated circuit according to claim 15, wherein delay time in the fourth and fifth delay sections is set so that standards for hold time at the time of the input data being input to the second latch section will be met at a normal operation time.

17. The semiconductor integrated circuit according to claim 15, wherein the sixth delay section delays the input data so that setup time at the time of the input data being input to the second latch section will shorten.

18. The semiconductor integrated circuit according to claim 15, wherein when both the fifth and sixth delay sections are bypassed, the input data is delayed so that hold time at the time of the input data being input to the second latch section will shorten.

19. The semiconductor integrated circuit according to claim 15, wherein select and non-select for the second, third, fifth, and sixth delay sections can be specified by a control signal which is input from the outside or which is output from an internal register.
